(19) United States
(12) Patent Application Publication
(10) Pub. No.: US 2024/0353344 A1
(43) Pub. Date: Oct. 24, 2024

(54) FILM THICKNESS MEASUREMENT DEVICE, FILM THICKNESS MEASUREMENT METHOD AND SUBSTRATE POLISHING DEVICE

(71) Applicant: EBARA CORPORATION, Tokyo (JP)

(72) Inventors: Masaki KINOSHITA, Tokyo (JP); Keita YAGI, Tokyo (JP); Taro TAKAHASHI, Tokyo (JP); Yoichi SHIOKAWA, Tokyo (JP); Yuki WATANABE, Tokyo (JP)

(21) Appl. No.: 18/634,702

(22) Filed: Apr. 12, 2024

(30) Foreign Application Priority Data
Apr. 20, 2023 (JP) 2023-069447

(51) Int. Cl. G01N 21/84; G01N 21/95; H01L 21/304; H01L 21/66

(52) U.S. Cl. CPC G01N 21/8422; G01N 21/9501; H01L 21/304; H01L 22/12

(57) ABSTRACT

Provided is a film thickness measurement device, including: a head that holds a substrate to be polished and is capable of moving the substrate, a stage made of transparent material; a liquid supply unit configured to supply liquid onto the stage; a liquid discharge unit configured to discharge the liquid on the stage to the outside; a measurement unit configured to be placed on a side opposite to the head across the stage and to optically measure a film thickness on a surface of the substrate that is placed across the stage; and a control unit configured to move at least one of the stage and the head toward the other, and to irradiate the substrate with light while the surface of the substrate is immersed in the liquid, thereby performing film thickness measurement.

### CROSS REFERENCE TO RELATED APPLICATION

This document claims priority to Japanese Patent Application No. 2023-069447 filed Apr. 20, 2023, the entire contents of which are hereby incorporated by reference.

### BACKGROUND

### Technical Field

The present invention relates to a film thickness measurement device and method for measuring a film thickness of a substrate such as a semiconductor wafer, and a substrate polishing device including the film thickness measurement device.

### Related Art

In a manufacturing process of a semiconductor device, a polishing device for polishing a surface of a substrate such as a semiconductor wafer is widely used. In such a polishing device, the substrate sent to the polishing unit is rotated in a state of being held by a substrate holding device called a top ring or a polishing head, and in this state, the substrate surface is pressed against the polishing surface of a polishing pad while rotating the polishing table together with the polishing pad, and the substrate surface is brought into sliding contact with the polishing surface in the presence of a polishing liquid, whereby the substrate surface is polished.

Such a substrate polishing device is provided with a film thickness measurement device for measuring a film thickness of the substrate, and for example, an in-line film thickness measurement device for measuring a film thickness of the substrate before the start of substrate polishing or after the end of substrate polishing, and an in-situ film thickness measurement device for measuring a film thickness of the substrate during polishing are known.

The in-line film thickness measurement device is provided outside a polishing unit and a cleaning unit, for example, and measures a film thickness of the substrate polished by the polishing unit and subjected to cleaning/drying processing by the cleaning unit. By drying the substrate during the polishing step and measuring a film thickness, it is possible to measure a film thickness with high accuracy. However, in this case, a water mark may be produced on the surface of the substrate after drying, and the throughput of the substrate treatment is deteriorated because the cleaning and drying steps need to be performed.

Meanwhile, a film thickness of the substrate can be determined by providing a film thickness measurement device between the polishing unit and the cleaning unit, irradiating the substrate surface with light through liquid filled in a nozzle close to the substrate surface while supplying rinse water to the entire substrate surface on the substrate stage, and measuring the spectrum of the reflected light (JP patent publication 2015-16540A).

### SUMMARY

In a case where a film thickness of the substrate is measured by the film thickness measurement device provided between the polishing unit and the cleaning unit, the film thickness measurement is performed after the polishing is completed. Therefore, in a case where the substrate is continuously polished a plurality of times by a plurality of polishing tables, it is not possible to identify the polishing result (film thickness) obtained from the polishing table immediately before, and it is also not possible to accurately control the polishing accuracy.

One aspect of the present invention is a film thickness measurement device that measures a film thickness of a substrate while the substrate is held by a movable head, the device including: a stage made of transparent material; a liquid supply unit configured to supply liquid onto the stage; a liquid discharge unit configured to discharge the liquid on the stage to the outside; a measurement unit configured to be placed on a side opposite to the head across the stage and to optically measure a film thickness on a surface of the substrate that is placed across the stage; and a control unit configured to move at least one of the stage and the head toward the other, and to drive the measurement unit to irradiate the substrate with light while the surface of the substrate is immersed in the liquid.

One aspect of the present invention is a substrate polishing device including a polishing table having a polishing surface for polishing the substrate; a top ring that holds the substrate with a membrane and presses it toward the polishing surface while enclosing an outer periphery of the substrate with a retainer ring; and a film thickness measurement device that measures a film thickness of the substrate after polishing treatment,
wherein, the top ring is movable between a polishing position where the substrate is polished above the polishing table and a delivery position where the substrate is delivered to a lateral side of the polishing table, and the film thickness measurement device is provided corresponding to a film thickness measurement position between the polishing position and the delivery position, and
wherein the film thickness measurement device includes: a stage made of transparent material, a liquid supply unit configured to supply liquid onto the stage; a liquid discharge unit configured to discharge the liquid on the stage to the outside; a measurement unit configured to be placed on a side opposite to the head across the stage and to optically measure a film thickness on a surface of the substrate that is placed across the stage; and a control unit configured to move at least one of the stage and the head toward the other, and to drive the measurement unit to irradiate the substrate with light while the surface of the substrate is immersed in the liquid.

### BRIEF DESCRIPTION OF DRAWINGS

FIG. 1 is a plan view illustrating a schematic configuration of a substrate polishing device including a film thickness measurement device according to one embodiment of the present invention;

FIG. 2 is a plan view illustrating a configuration of a polishing unit;

FIG. 3 is a perspective view illustrating the configuration of the polishing unit;

FIG. 4 is a schematic cross-sectional view illustrating an internal configuration of the polishing unit;

FIG. 5 is a plan view illustrating a state in which the substrate moves among a delivery position, a film thickness measurement position and a polishing position;

FIG. 6 is an explanatory diagram illustrating a configuration of a film thickness measurement device;

FIG. 7 is a plan view illustrating a state in which liquid is supplied to the film thickness measurement device;

FIGS. 8A and 8B are explanatory diagrams illustrating operations of the film thickness measurement device, in which FIG. 8A illustrates a state in which a substrate surface is not in contact with a liquid region, and FIG. 8B illustrates a state in which the substrate surface is in contact with the liquid region;

FIG. 9 is an explanatory diagram schematically illustrating a configuration of a control unit;

FIG. 10 is a flowchart illustrating operations of a substrate polishing device;

FIGS. 11A and 11B are plan views illustrating another example of the film thickness measurement device; and

FIG. 12 is a side view illustrating still another example of the film thickness measurement device.

### DETAILED DESCRIPTION

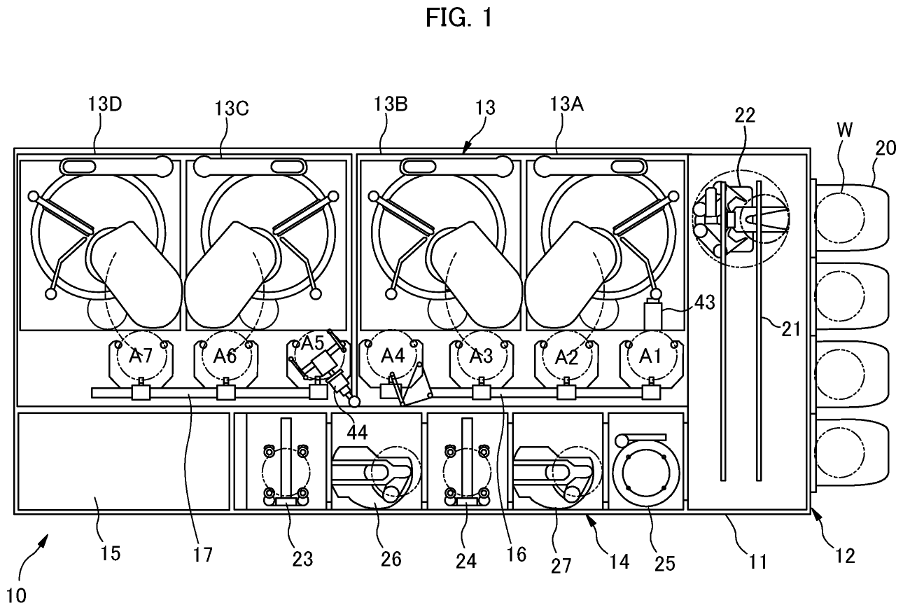

Hereinafter, embodiments of the present invention will be described with reference to the drawings. FIG. 1 shows a schematic configuration of a substrate polishing device including a film thickness measurement device according to the present embodiment. A substrate polishing device 10 includes a rectangular housing 11, and is defined to include a load/unload unit 12, a polishing unit 13, and a cleaning unit 14. The substrate polishing device 10 also includes a control unit 15 that controls operations of each unit.

The load/unload unit 12 includes a plurality of front load units in which a substrate cassette 20 for accommodating a large number of substrates W such as semiconductor wafers are set. The load/unload unit 12 is provided with a traveling mechanism 21 on which a transfer robot 22 movable along the arrangement of the substrate cassettes 20 is installed. The transfer robot 22 receives a substrate W before being polished from the substrate cassette 20, transfers the substrate W toward the polishing unit 13, and receives the substrate W subjected to the polishing/cleaning treatment from the cleaning unit 14.

The polishing unit 13 includes a plurality of polishing units 13A to 13D for polishing (planarizing) the substrate W. The first polishing unit 13A to the fourth polishing unit 13D are arranged along a longitudinal direction of the substrate polishing device 10. Details of the configuration of the polishing unit will be described later.

A first linear transporter 16 is disposed adjacent to the first polishing unit 13A and the second polishing unit 13B. The first linear transporter 16 transports the substrate W between four transport positions (a first transport position A1 to a fourth transport position A4 in order from a side of the load/unload unit 12) along a direction in which the polishing units 13A and 13B are arranged.

A second linear transporter 17 is disposed adjacent to the third polishing unit 13C and the fourth polishing unit 13D. The second linear transporter 17 transports the substrate W between three transport positions (a fifth transport position A5 to a seventh transport position A7 in order from the side of the load/unload unit 12) along a direction in which the polishing units 13C and 13D are arranged.

The cleaning unit 14 accommodates a first cleaning unit 23 and a second cleaning unit 24 that clean the polished substrate W, and a drying unit 25 that dries the cleaned substrate W. A first transport unit 26 is disposed between the first cleaning unit 23 and the second cleaning unit 24 to deliver and receive the substrate W therebetween. A second transport unit 27 is disposed between the second cleaning unit 24 and the drying unit 25 to deliver and receive the substrate W therebetween.

In the first cleaning unit 23, a plurality of (for example, two) primary cleaning modules are arranged vertically. Similarly, in the second cleaning unit 24, a plurality of (for example, two) secondary cleaning modules are arranged vertically. The primary cleaning module and the secondary cleaning module are cleaning machines that clean the substrate using cleaning liquid, and by arranging the primary cleaning modules and the secondary cleaning modules on top of each other, a footprint thereof can be reduced.

As the primary cleaning module and the secondary cleaning module, a roll sponge cleaning machine can be used. The primary cleaning module and the secondary cleaning module may be cleaning modules of the same type, or may be cleaning modules of different types. For example, the primary cleaning module may be a cleaning machine that scrubs upper and lower surfaces of the substrate with a pair of roll sponges, and the secondary cleaning module may be a pencil sponge cleaning machine or a two-fluid jet cleaning machine.

In the drying unit 25, a plurality of (for example, two) drying modules are arranged vertically, and the substrate W is dried by ejecting gas from a nozzle (not illustrated) toward the rotating substrate W. Alternatively, the substrate W may be rotated at a high speed to dry the substrate W by centrifugal force. The transfer robot 22 takes out the cleaned and dried substrate W from the drying unit 25 and returns the substrate W to the substrate cassette 20.

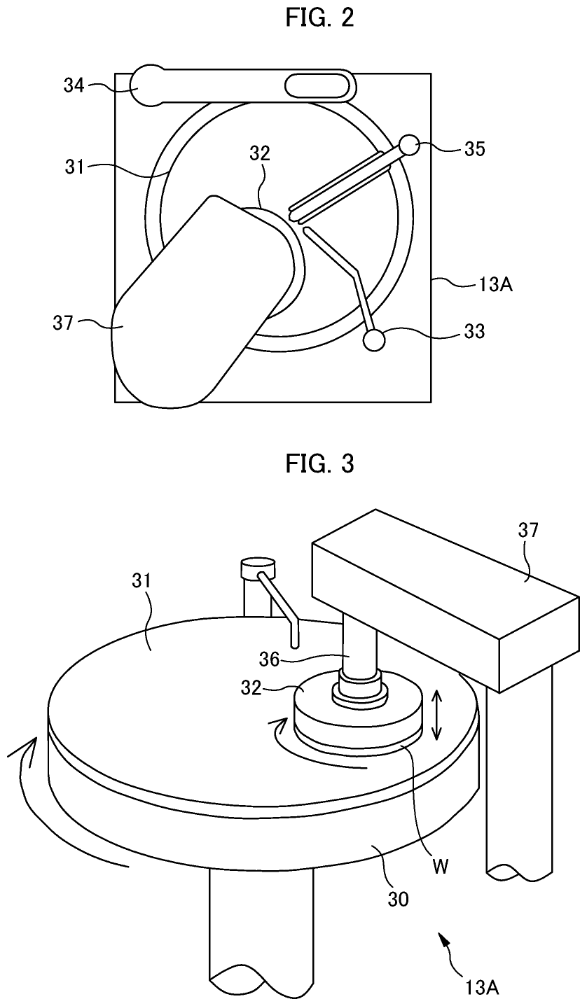

FIGS. 2 and 3 illustrate a schematic configuration of the first polishing unit 13A according to the present embodiment. Since the second polishing unit 13B to the fourth polishing unit 13D have the same configuration as that of the first polishing unit 13A, the first polishing unit 13A will be described below.

The first polishing unit 13A includes a polishing table 30 to which a polishing pad 31 having a polishing surface is attached, a top ring 32 (corresponding to the head) for holding the substrate W and polishing the substrate W while pressing the substrate W against the polishing pad 31 on the polishing table 30 at a predetermined pressure, a polishing liquid supply nozzle 33 for supplying polishing liquid or a dressing liquid (for example, pure water) to the polishing pad 31, a dresser 34 for dressing the polishing surface of the polishing pad 31, and an atomizer 35 for atomizing a mixture fluid of liquid (for example, pure water) and gas (for example, nitrogen gas), or alternatively, liquid only (for example, pure water), and jetting the atomized mixture fluid or liquid to the polishing surface. The top ring 32 is rotatable by a swing arm 37 connected via a top ring shaft 36.

The polishing pad 31 attached onto the polishing table 30 constitutes the polishing surface for polishing the substrate W. Note that fixed abrasive grains can be used instead of the polishing pad 31. The top ring 32 and the polishing table 30 are configured to rotate about the axis thereof as indicated by arrows in FIG. 3. The substrate W is held on a lower surface of the top ring 32 by vacuum suction. The polishing liquid is supplied from the polishing liquid supply nozzle 33 to an upper surface (polishing surface) of the polishing pad 31, and the substrate W is pressed against the polishing pad 31 by the top ring 32 and polished.

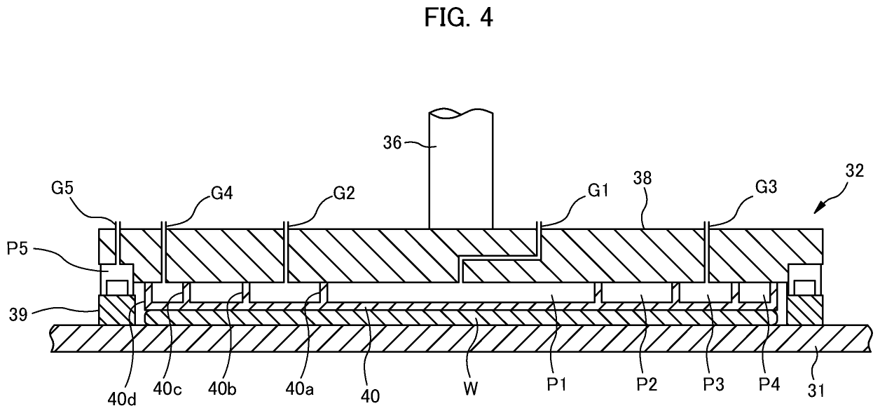

In FIG. 4, the top ring 32 is connected to a lower end of the top ring shaft 36 via a universal joint (not shown) that is a ball joint. The top ring 32 includes a substantially disk-shaped top ring main body 38, a retainer ring 39 disposed below the top ring main body 38, and a circular membrane (elastic pad) 40 that abuts on the substrate W. The top ring main body 38 is made of a material having high strength and rigidity such as metals or ceramics.

The retainer ring 39 is disposed so as to enclose the top ring main body 38 and the membrane 40. The retainer ring 39 is a member made of a ring-shaped resin material in contact with the upper surface (polishing surface) of the polishing pad 31, is disposed so as to enclose an outer peripheral edge of the substrate W held by the top ring main body 38, and supports the outer peripheral edge of the substrate W so that the substrate W being polished does not protrude from the top ring 32. The retainer ring 39 is configured to be movable in a vertical direction (vertical direction in the drawing). In other words, the retainer ring 39 can displace a relative position of the top ring 32 with respect to the substrate W in the vertical direction.

The membrane 40 is attached to the lower surface of the top ring main body 38. A plurality of pressure chambers (airbags) P1, P2, P3, and P4 are formed between the membrane 40 and the top ring main body 38 by a plurality of partition walls 40a to 40d formed on the membrane 40. Pressurized fluid such as pressurized air is supplied to the pressure chambers P1, P2, P3, and P4 through fluid passages G1, G2, G3, and G4, respectively, or the pressure chambers P1, P2, P3, and P4 are evacuated. The central pressure chamber P1 is circular, the other pressure chambers P2, P3, and P4 are annular, and the pressure chambers P1, P2, P3, and P4 are concentrically arranged. The internal pressures of the pressure chambers P1, P2, P3, and P4 can be varied independently of each other by a pressure adjusting unit (not illustrated), whereby the pressing forces on four regions of the substrate W, that is, a central portion, an inner intermediate portion, an outer intermediate portion, and a peripheral portion, can be adjusted independently.

In order to prevent the substrate W being polished from jumping out of the top ring 32, the outer peripheral portion of the substrate W is held while being enclosed by the retainer ring 39 provided on the lower surface of the top ring 32. An opening is formed in a portion constituting the pressure chamber P3 of the membrane 40, and the substrate W is adsorbed and held by the top ring 32 by forming a vacuum in the pressure chamber P3. By supplying, for example, nitrogen gas, dry air or compressed air to the pressure chamber P3, the substrate W is released from the top ring 32.

An elastic bag forming the pressure chamber P5 is disposed between the retainer ring 39 and the top ring main body 38. The retainer ring 39 is movable up and down relative to the top ring main body 38. The fluid passage G5 communicates with the pressure chamber P5, and pressurized fluid such as pressurized air is supplied to the pressure chamber P5 through the fluid passage G5. The internal pressure of the pressure chamber P5 can be adjusted by the pressure adjusting unit, and the pressing force of the retainer ring 39 against the polishing pad 31 can be adjusted independently of the pressing force against the substrate W.

A film thickness measurement device (not shown) including an optical sensor and a processing unit is provided below the polishing pad 31, and the film thickness of the substrate W is measured in-situ by irradiating the substrate W with light from below and analyzing the spectrum of the reflected light.

The substrate W may be polished by any of the first polishing unit 13A, the second polishing unit 13B, the third polishing unit 13C, and the fourth polishing unit 13D, or may be continuously polished by a plurality of polishing units selected in advance from these polishing units 13A to 13D. By equalizing all the polishing times of the polishing units 13A to 13D, the throughput can be improved.

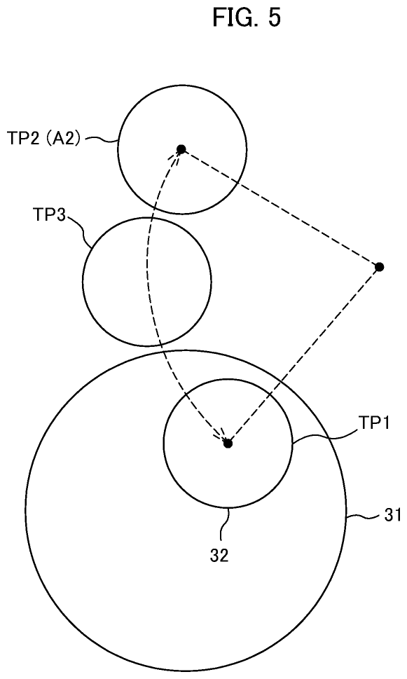

In FIG. 1, the substrate W is conveyed to the polishing units 13A and 13B by the first linear transporter 16. The top ring 32 of the first polishing unit 13A moves between a polishing position above the polishing table 30 (polishing pad 31) and the second transport position A2 on a side of the polishing table 30. The substrate is delivered to the top ring 32 at the second transport position A2, and the second transport position A2 becomes a delivery position TP2 (see FIG. 5).

Similarly, the top ring of the second polishing unit 13B (third polishing unit 13C or fourth polishing unit 13D) moves between the polishing position above the polishing table (polishing pad) and the third transport position A3 (sixth transport position A6 for the third polishing unit 13C and seventh transport position A7 for the fourth polishing unit 13D) on the side of the polishing table. The substrate is delivered to the top ring at the third transport position A3 (sixth transport position A6 or seventh transport position A7) as a substrate delivery position.

A lifter 43 for receiving the substrate from the transfer robot 22 is disposed at the first transport position A1. The substrate is handed over from the transfer robot 22 to the first linear transporter 16 via the lifter 43. Further, a swing transporter 44 having a reversing function is disposed among the first linear transporter 16, the second linear transporter 17 and the cleaning unit 14, and delivers the substrate from the first linear transporter 16 to the second linear transporter 17 and delivers the substrate from the polishing unit 13 to the cleaning unit 14.

FIG. 5 schematically illustrates a positional relationship among the polishing table 30 (polishing pad 31), the top ring 32, and a film thickness measurement unit 50 of the first polishing unit 13A. The top ring 32 is rotatable by a swing arm 37 connected via the top ring shaft 36, and is configured to move among a polishing position TP1 above the polishing table 30, a delivery position TP2 (second transport position A2) on the side of the polishing table 30, and a film thickness measurement position TP3 between the polishing position TP1 and the delivery position TP2. The film thickness measurement unit 50 for performing in-line wet film thickness measurement described later is disposed at a position corresponding to the film thickness measurement position TP3 of the top ring 32. Configurations of the top ring 32 and the film thickness measurement unit 50 are the same in the second polishing unit 13B to the fourth polishing unit 13D, and a detailed description thereof will be omitted.

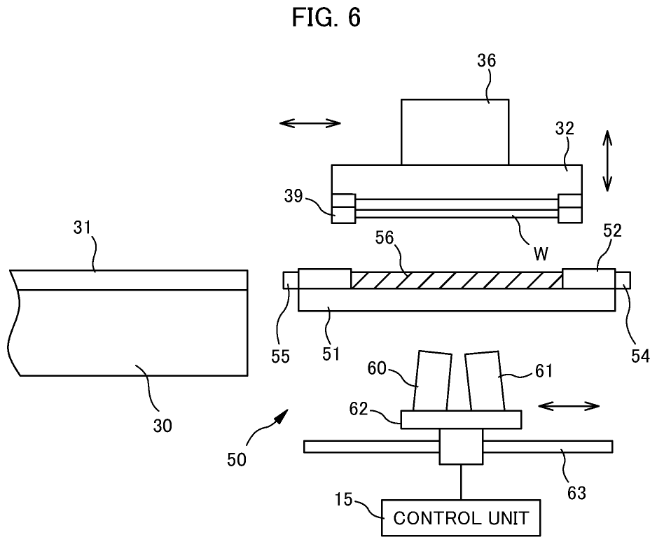

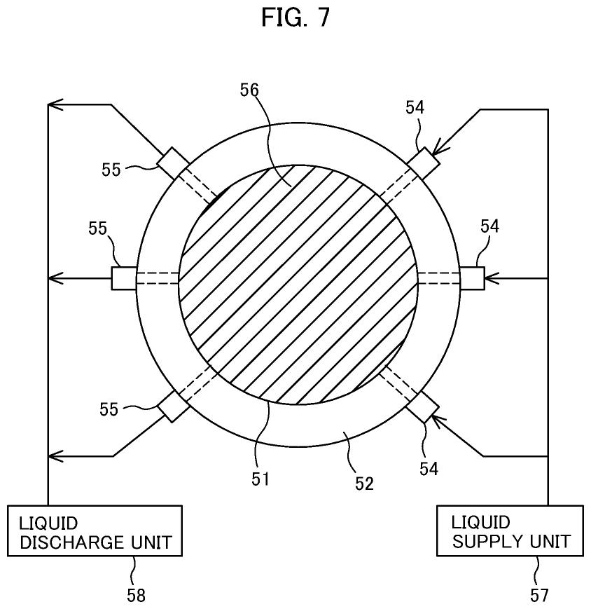

FIGS. 6 and 7 are views illustrating a configuration of the film thickness measurement unit 50. The film thickness measurement unit 50 is disposed below a region through which the top ring 32 passes on the side of the polishing table 30. The film thickness measurement unit 50 includes a transparent stage 51, an annular ring member 52, a supply line 54 for supplying liquid (for example, pure water) to the transparent stage, and a discharge line 55.

The stage 51 is made of a transparent material. The transparent material of the stage 51 is, for example, glass, quartz, acrylic resin, polyethylene terephthalate, polyvinyl chloride, polystyrene, polycarbonate, or polyurethane. The stage 51 supports the liquid supplied from the supply line 54 and allows incident light from a light source 60 and reflected light from the substrate W to pass therethrough. The ring member 52 for holding the liquid supplied from the supply line 54 so as not to spill is installed on an outer peripheral portion of the stage 51. The ring member 52 is preferably made of a softer material (for example, foamable polyurethane) than the retainer ring 39, but the ring member 52 and the stage 51 may be integrally molded.

The supply line 54 and the discharge line 55 are provided so as to penetrate the ring member 52 from the outside of the stage 51. A liquid supply unit 57 is connected to the upstream side of the supply line 54, and liquid is supplied from the liquid supply unit 57 onto the stage 51 (region enclosed by the ring member 52) via the supply line 54. A liquid discharge unit 58 is connected to the downstream side of the discharge line 55, and liquid in the liquid region 56 on the stage 51 enters through the discharge line 55 and is discharged to the outside of the film thickness measurement unit 50. The liquid supply unit 57 and the liquid discharge unit 58 may be connected to circulate and supply the liquid.

The supply line 54 and the discharge line 55 are disposed opposite to each other with respect to the center of the stage 51. In the example of FIG. 7, three supply lines 54 are disposed on a right side, and three discharge lines 55 are disposed on a left side. Consequently, a direction of the liquid supplied from the supply line 54 to the stage 51 is aligned, and the liquid on the stage 51 can be prevented from staying. In the example of FIG. 7, three supply lines 54 and three discharge lines 55 are arranged, but the number can be appropriately altered.

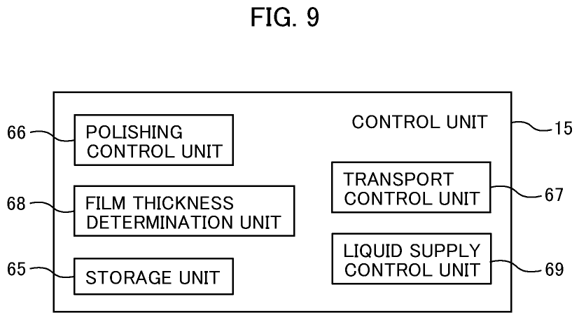

The film thickness measurement unit 50 includes a light emitting unit 60 and a light receiving unit 61 disposed on a base 62, and these units constitute the measurement unit. The light emitting unit 60 is, for example, a light source that emits light of multiple wavelengths, and irradiates the surface (polished surface) of the substrate W with light via the stage 51. The light receiving unit 61 is, for example, a multi-wavelength spectral imaging device (hyperspectral camera) including a linear sensor in which light receiving elements are arranged along a direction perpendicular to a paper surface, and captures reflected light from the substrate W and decomposes the reflected light according to a wavelength to generate a linear image signal (reflection spectrum image) reflecting a reflected light intensity for each wavelength. The reflection spectrum image is a signal reflecting the film thickness of the substrate W for each wavelength, and is sent to a film thickness determination unit 68 (see FIG. 9).

The base 62 is movable along a guide rail 63 in a left-right direction in the drawing, and slides together with the light emitting unit 60 and the light receiving unit 61 by a driving mechanism (not shown). The entire surface of the substrate W can be imaged by receiving light from the light emitting unit 60 by the light receiving unit 61 which is a sensor on the line while sliding the base 62. In addition to this embodiment, for example, the entire surface of the substrate W may be imaged by rotating the top ring 32 or the light receiving unit 61, or the light receiving unit 61 may be configured as a planar image sensor.

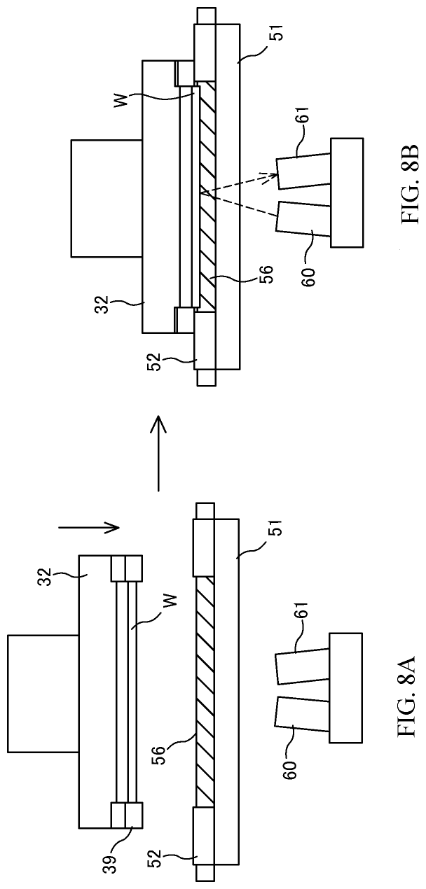

The top ring 32 holding the substrate W after the polishing treatment moves from the polishing position TP1 toward the film thickness measurement position TP3. A rotational position of the swing arm 37 connected via the top ring shaft 36 is set in advance according to a drive amount of a rotation motor (not shown) that rotates the swing arm 37, and the position of the top ring 32 is thereby controlled. When it is detected that the top ring 32 holding the substrate after the polishing treatment reaches the film thickness measurement position TP3 (see FIG. 8A), the top ring 32 stops moving in a horizontal direction and moves in a downward direction in the drawing toward the stage 51. Alternatively, arrival at the film thickness measurement position TP3 may be detected using a position sensor installed on the stage 51.

Instead of moving the top ring 32 downwardly toward the stage 51 as illustrated in FIG. 8A, the stage 51 may be moved upwardly toward the top ring 32. In this case, a lifting mechanism (for example, a lifting cylinder (not shown)) for lifting the stage 51 is connected to the stage 51. Further, the top ring 32 may be moved downward and the stage 51 may be moved upward to approach to each other. That is, an operation of bringing the relative positions closer by movement of at least one of the top ring 32 and the stage 51 may be performed. Hereinafter, a description will be given using an example in which the top ring 32 moves downward as illustrated in FIG. 8A.

In FIG. 8A, the liquid region 56 formed by the liquid supplied from the supply line 54 exists on the stage 51. In this state, when the top ring 32 moves downward in the drawing, as illustrated in FIG. 8B, the retainer ring 39 is lifted by the ring member 52, and the polished surface of the substrate W is held in contact with the liquid on the stage 51. In other words, by displacing the relative position of the top ring 32 with respect to the substrate W of the retainer ring 39 to a side opposite to the stage 51 by the ring member 52, the polished surface of the substrate W is held in contact with the liquid on the stage 51. In this state, since an inner diameter of the ring member 52 is larger than a diameter of the substrate W, the outer peripheral portion of the substrate W and the ring member 52 do not come into contact with each other.

Furthermore, the inner diameter of the ring member 52 is larger than an inner diameter of the retainer ring 39 and smaller than an outer diameter of the retainer ring 39. Accordingly, the ring member 52 can contact only the retainer ring 39 outside the substrate W, and thus the retainer ring 39 can be lifted up.

The annular ring member 52 is exemplified in the present embodiment, however the shape and dimension may be altered or modified to the extent capable of lifting the retainer ring 39 up. For example, the ring member 52 may be a polygonal annular member including a triangle and a square. In this case, in order to lift the retainer ring 39, only a portion of the inner diameter of the ring member 52 needs to be smaller than the outer diameter of the retainer ring 39. Consequently, only a part of the ring member 52 comes into contact with the retainer ring 39, and the retainer ring 39 can be lifted up. Also in this case, the inner diameter of the ring member 52 is defined to be larger than the inner diameter of the retainer ring 39 over the entire ring member 52.

In a state where the substrate W is in contact with the liquid on the stage 51, the light emitting unit 60 and the light receiving unit 61 are driven, and the film thickness of the substrate W is measured. In this state, the liquid region 56 filled with liquid (pure water) having a certain level is interposed between the substrate W and the transparent stage 51, and measurement is performed without drying the surface of the substrate W, so that formation of watermarks and decrease in throughput can be suppressed.

The liquid supply from the supply line 54 may be always performed during the operation of the polishing unit 13A. Alternatively, the liquid supply may be initiated after the polishing treatment on the substrate W is finished, and the liquid supply may be ended at a timing when the substrate W after the film thickness measurement is moved to the delivery position TP2. This makes it possible to save the amount of liquid supplied.

The liquid supplied from the supply line 54 may be degassed water in which dissolved oxygen content is suppressed. By supplying the degassed water, it is possible to suppress generation of oxides on the substrate surface due to the substrate surface in contact with the liquid at the time of measurement that receives light and reacts with dissolved oxygen upon measurement.

The liquid supplied from the supply line 54 may be cleaning liquid (chemical solution) such as acidic aqueous solution or alkaline aqueous solution. Examples of the acidic aqueous solution include hydrofluoric acid, oxalic acid, citric acid, hydrochloric acid, and sulfuric acid. Examples of the alkaline aqueous solution include ammonia water and tetramethylammonium hydroxide (TMAH). After the cleaning liquid is supplied, the supply may be switched to pure water at the time of measuring the film thickness. Using the cleaning liquid, polishing residue can be easily removed from the substrate surface.

When the film thickness measurement is completed, the top ring 32 moves upward in FIGS. 8A and 8B, and the substrate W moves to a position away from the film thickness measurement unit 50. Then, the top ring 32 moves to the delivery position TP2 to hand over the substrate W.

The control unit 15 controls operations of each unit of the substrate polishing device 10 and is disposed inside the housing 11. The control unit 15 is, for example, a general-purpose computer device, and includes, for example, a CPU, a storage unit (memory) 65 that stores a control program, and a display unit. Further, the control unit 15 is provided with an input unit that receives external inputs. The external inputs may include a mechanical operation by a user and a signal input from an external device in a wired or wireless manner.

The control unit 15 controls the movement of each unit of the substrate polishing device 10 by activating a control program stored in the storage unit (memory) 65. The control program for controlling the operations of the substrate polishing device 10 may be installed in advance in a computer constituting the control unit 15, or may be stored in a storage medium such as a DVD, a BD, or an SSD, or may be installed in the control unit 15 via the Internet.

FIG. 9 illustrates one example of a functional block diagram of the control unit 15 included in the substrate polishing device 10. The control unit 15 includes a storage unit 65, a polishing control unit 66, a transport control unit 67, a film thickness determination unit 68, and a liquid supply control unit 69. The polishing control unit 66 controls the rotation of the polishing table 30 and the top ring 32, controls the pressures of the pressure chambers P1 to P5, determines whether the polishing amount of the substrate W reaches a set value by, for example, an optical sensor disposed below the polishing table 30, and terminates the substrate polishing when the polishing amount reaches the set value. The transport control unit 67 controls the transport of the substrate W in the substrate polishing device 10, including the transport of the substrate Win the polishing units 13A to 13D.

The film thickness signal processing unit 68 stores a spectrum image group including a plurality of reference spectrum images corresponding to pieces of different film thickness data for each different wavelength. The film thickness signal processing unit 68 selects a reference spectrum image having the closest shape to a reflection spectrum image (reflecting the film thickness of the substrate W) from the light receiving unit 61 by pattern matching, and calculates a film thickness corresponding to the reference spectrum as the film thickness of the substrate W.

The liquid supply control unit 69 controls operations of the liquid supply unit 57 and the liquid discharge unit 58 to control supply and discharge of liquid to and from the stage 53. Further, a water level sensor (not shown) may be provided on the stage 53 to control the water level of the liquid region 56.

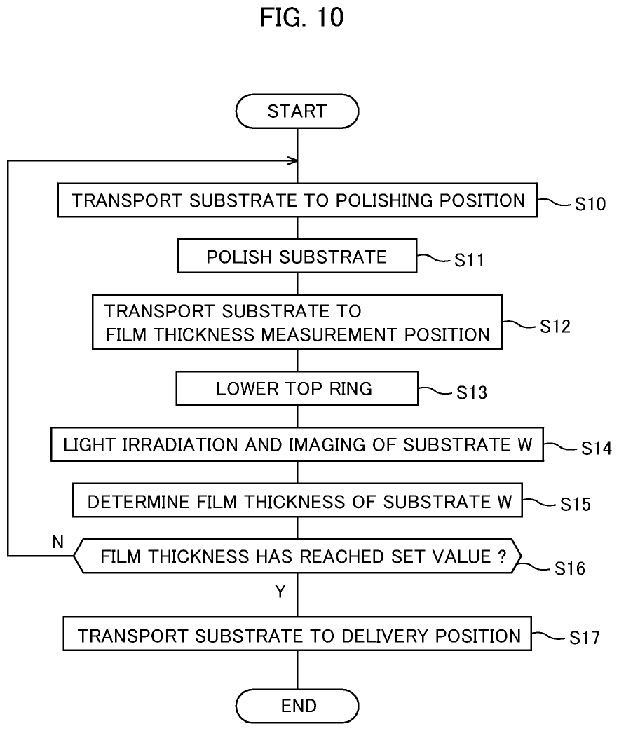

Hereinafter, substrate polishing and film thickness measurement processing in the substrate polishing device having the configuration above will be described with reference to a flowchart of FIG. 10. When the substrate W is transferred to the polishing unit 13A, the top ring 32 holds the substrate W at a position enclosed by the retainer ring 39 by vacuum suction, and transports the substrate W from the delivery position TP2 to the polishing position TP1 (step S10). The polishing unit 13A performs polishing processing on the substrate W by pressing the substrate W reaching the polishing position TP1 against the polishing pad 31 (step S11).

After the polishing process is completed, the top ring 32 is moved toward the film thickness measurement position TP3 (step S12). When it is detected that the top ring 32 reaches the film thickness measurement position TP3, the top ring 32 is lowered toward the stage 51 (step S13). Accordingly, the surface of the substrate W stops at a position in contact with the liquid region 56 on the stage 51.

When the substrate W is irradiated with light from the light emitting unit 60 in this state, the light receiving unit 61 receives the reflected light from the substrate W and measures the intensity of the reflected light over a predetermined wavelength range to generate a light intensity signal (step S14). The generated light intensity signal is sent to the film thickness determination unit 68, a surface image of the substrate W is generated for each wavelength from the received light intensity signal, a reference spectrum image having the closest shape to the image is selected, and a film thickness corresponding to the reference spectrum image is calculated as the film thickness of the substrate W (step S15).

During the film thickness measurement of the substrate W, liquid (pure water) having a uniform thickness is filled between the substrate W and the transparent stage 51, and the surface of the substrate W is in a uniform state, so that the film thickness can be measured with high accuracy. Further, since the pure water flows on the surface of the substrate W, impurities such as polishing residues (slurry or polishing waste) and bubbles remaining on the surface of the substrate W and/or between the peripheral edge of the substrate and the retainer ring can be removed.

During the measurement of the film thickness of the substrate W, the liquid flows only between the substrate W and the transparent stage 51, and the liquid does not come into contact with the light emitting unit 60 and the light receiving unit 61. Therefore, as compared with a case where the liquid comes into contact, the measurement accuracy is stabilized, and the possibility of malfunction of the light emitting unit 60 and the light receiving unit 61 due to wetting can be suppressed. Furthermore, since the liquid between the substrate W and the transparent stage 51 continues to flow, it is highly unlikely that the liquid and the polishing residue are stored on the stage.

Furthermore, since the substrate W is supported in a state where the ring member 52 on the stage 51 is in contact with the retainer ring 39 (not the substrate W), the film thickness can be measured in a state where the substrate W and the stage 51 are not in contact with each other. Since the retainer ring 39 is lifted upward and is positioned above the surface of the substrate W at the time of film thickness measurement, it is possible to prevent shadow of the retainer ring 39 from hiding the substrate W at the time of imaging the peripheral edge portion of the substrate W.

As a result of the film thickness measurement, it is determined whether the film thickness of the substrate W has reached the set value (step S16), and when it is detected that the film thickness has reached the set value, the top ring 32 moves to the delivery position TP2 (step S17), and transports the polished substrate W toward the cleaning unit 14. On the other hand, when the film thickness of the substrate W does not reach the set value, the substrate W is moved again to the polishing position TP1 (step S10), and the substrate polishing is performed again. Accordingly, the throughput of the substrate processing can be increased as compared with a case where the film thickness measurement is performed outside the polishing unit 13. Further, in a case where substrate polishing is continuously performed a plurality of times on a plurality of polishing tables, it is possible to identify a polishing result (film thickness) obtained from the polishing table immediately before, and thus, it is possible to accurately control polishing accuracy.

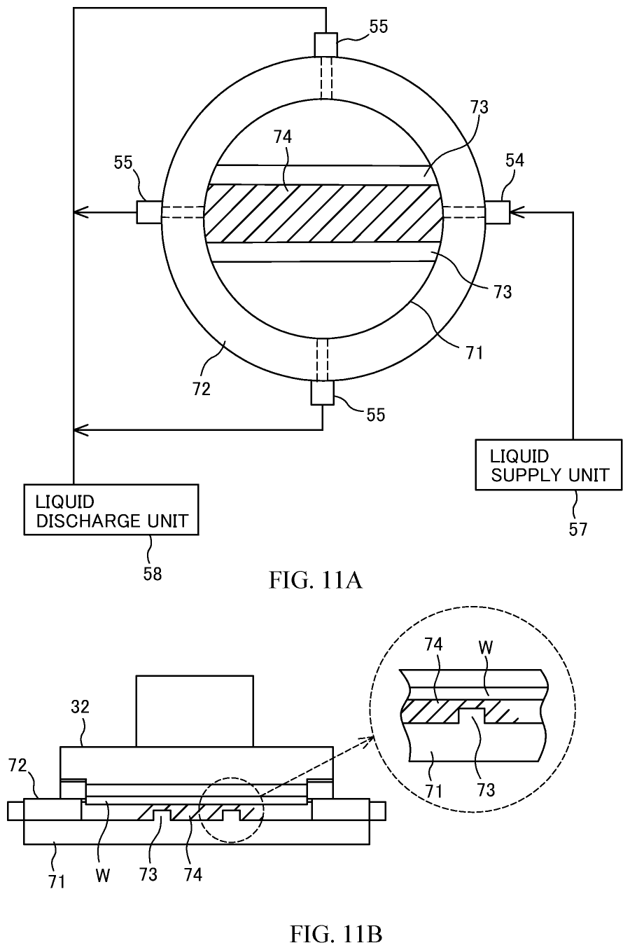

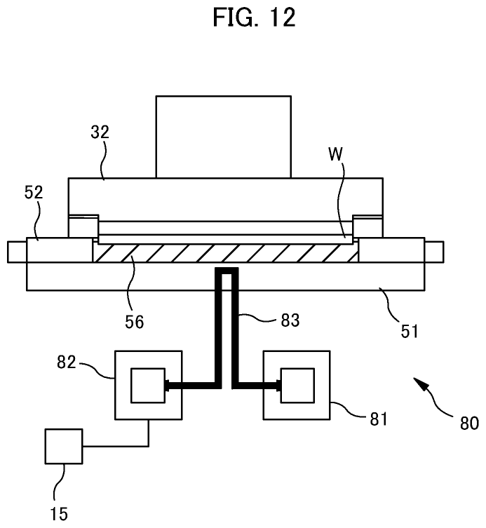

In the above embodiment, the film thickness is measured in a state where the entire surface of the substrate W is immersed in the liquid (pure water). However, as illustrated in FIG. 11A, a pair of ridges 73 may be provided with the center of the stage 71 interposed therebetween, and the liquid may be intensively immersed in a part of the substrate W (region 74 on the line including the center). Since the height of the ridge 73 is lower than the height of the ring member 52 (see FIG. 11B), the ridge 73 and the substrate W are prevented from coming into contact with each other. Therefore, the liquid 74 leaks to the outside (region between the ridge 73 and the ring member 52 on the stage 71) through the gap between the ridge 73 and the substrate W, but the leaked liquid is discharged to the liquid discharge unit 58 through a pair of discharge lines 55 (upper and lower discharge lines 55 in FIG. 11A) provided outside the stage 71.

In the above embodiment, a case where a wavelength spectroscopic imaging device (hyperspectral camera) is used as the light receiving unit has been described as the example, but the present invention is not limited thereto, and the film thickness may be measured by another measurement method. FIG. 12 illustrates another embodiment of the film thickness measurement device, and a film thickness measurement device 80 includes a light projecting unit 81 and a light receiving unit 82, and the operations thereof are integrally controlled by the control unit 15.

The light projecting unit 83 irradiates the polished surface of the substrate W with light. The light receiving unit 82 includes a spectroscope that receives the reflected light returned from the substrate W, decomposes the reflected light according to the wavelength, and measures the intensity of the reflected light over a predetermined wavelength range. The light projecting unit 81 and the light receiving unit 82 are connected via a pair of optical fibers 85 arranged in parallel with each other.

The light receiving unit 82 measures the intensity of the reflected light at each wavelength over a predetermined wavelength range, and transmits the obtained light intensity data to the control unit 15. The light intensity data is an optical signal reflecting the film thickness of the substrate W, and includes the intensity of the reflected light and the corresponding wavelength. As an algorithm for estimating the film thickness of the substrate W, for example, a reference spectrum (Fitting Error) algorithm, a fast Fourier transform (FFT) algorithm, or a peak valley (Peak Valley) method can be used.

For the reference spectrum method, a plurality of spectrum groups including a plurality of reference spectra corresponding to different film thicknesses are prepared. A spectrum group including a spectrum signal (reflectance spectrum) from a spectrum generation unit 60 and a reference spectrum having the closest shape is selected. During wafer polishing, a measurement spectrum for measuring the film thickness is generated, a reference spectrum having the closest shape is selected from the selected spectrum group, and a film thickness corresponding to the reference spectrum is estimated as the film thickness of the wafer being polished. A profile is obtained by acquiring information on the film thickness estimated by this method at a plurality of points in a radial direction of the wafer W.

The embodiments stated above have been described for the purpose of enabling those skilled in the art to implement the present invention. It will be appreciated to those skilled in the art that various modifications would be allowable to the extent not departing from the gist of the present invention, and the technical idea of the present invention could also be applied to other embodiments. The present invention is not limited to such embodiments, but should be interpreted in the broadest scope according to the technical idea defined by the accompanying claims.

What is claimed is:

1. A film thickness measurement device that measures a film thickness of a substrate while the substrate is held by a movable head, the device comprising:
a stage made of transparent material;
a liquid supply unit configured to supply liquid onto the stage;
a liquid discharge unit configured to discharge the liquid on the stage to the outside;
a measurement unit configured to be placed on a side opposite to the head across the stage and to optically measure a film thickness on a surface of the substrate that is placed across the stage; and
a control unit configured to move at least one of the stage and the head toward the other, and to drive the measurement unit to irradiate the substrate with light while the surface of the substrate is immersed in the liquid.

2. The film thickness measurement device according to claim 1, wherein
the head includes a retainer ring that surrounds an outer periphery of the substrate and is capable of displacing a relative position in the head with respect to the substrate,
the stage holds the liquid and includes an annular member having an inner diameter larger than the diameter of the substrate, and
when at least one of the stage and the head moves toward the other, the retainer ring abuts the annular member and displaces the relative position to a side opposite to the stage.

3. The film thickness measurement device according to claim 1, wherein
the head is configured to be rotatable, and
the control unit is configured to drive the measurement unit to irradiate the substrate with light while rotating the head with the surface of the substrate immersed in the liquid.

4. The film thickness measurement device according to claim 1, wherein liquid is continuously supplied and discharged to the stage while the film thickness of the substrate is measured.

5. The film thickness measurement device according to claim 2, wherein a pair of ridges that limits a region to which the liquid is supplied is provided on the stage, and a height of the ridges is lower than that of the annular member.

6. The film thickness measurement device according to claim 1, wherein the measurement unit is configured to be movable relative to the stage.

7. A film thickness measurement method, the method comprising:
moving a substrate to a film thickness measurement position by a head holding the substrate to be polished;
forming a liquid region on a stage made of a transparent material by supplying liquid from a liquid supply unit toward the stage;
moving at least one of the stage and the substrate so as to move toward the other until a surface of the substrate is immersed in the liquid region on the stage; and
optically measuring the film thickness of the substrate by a measurement unit arranged on a side opposite to the head across the stage.

8. A substrate polishing device comprising:
a polishing table having a polishing surface for polishing a substrate;
a head that holds the substrate with a membrane and presses it toward the polishing surface while enclosing an outer periphery of the substrate with a retainer ring; and
a film thickness measurement device that measures a film thickness of the substrate after polishing treatment,
wherein,
the head is movable between a polishing position where the substrate is polished above the polishing table and a delivery position where the substrate is delivered to a lateral side of the polishing table, and
the film thickness measurement device is provided corresponding to a film thickness measurement position between the polishing position and the delivery position, and includes:
a stage made of transparent material,
a liquid supply unit configured to supply liquid onto the stage;
a liquid discharge unit configured to discharge the liquid on the stage to the outside;
a measurement unit configured to be placed on a side opposite to the head across the stage and to optically measure a film thickness on a surface of the substrate that is placed across the stage; and
a control unit configured to move at least one of the stage and the head toward the other, and to drive the measurement unit to irradiate the substrate with light while the surface of the substrate is immersed in the liquid.

9. A film thickness measurement device that measures a film thickness of a substrate while the substrate is held by a movable head, the head including a retainer ring that encloses an outer periphery of the substrate and is capable of displacing a relative position in the head, the measurement device comprising:
a stage made of a transparent material and holding a liquid;
a measurement unit configured to be placed on a side opposite to the head across the stage and to optically measure a film thickness on a surface of the substrate that is placed across the stage; and
a control unit configured to move at least one of the stage and the head toward the other, and to drive the measurement unit to irradiate the substrate with light while the surface of the substrate is immersed in the liquid,
wherein,
the stage includes an annular member having an inner diameter larger than a diameter of the substrate, and
when at least one of the stage and the head moves toward the other, the retainer ring abuts the annular member and displaces the relative position to a side opposite to the stage.
